(19) United States
(12) Patent Application Publication
(10) Pub. No.: US 2009/0081565 A1
(43) Pub. Date: Mar. 26, 2009

(54) METHOD FOR FORMING ETCHING MASK, CONTROL PROGRAM AND PROGRAM STORAGE MEDIUM

(75) Inventors: Koichi Yatsuda, Yamanashi (JP); Eiichi Nishimura, Yamanashi (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/234,032

(22) Filed: Sep. 19, 2008

Related U.S. Application Data
(60) Provisional application No. 60/991,490, filed on Nov. 30, 2007.

(30) Foreign Application Priority Data
Sep. 21, 2007 (JP) 2007-245002

(51) Int. Cl. H01L 21/02; G03F 1/00

(52) U.S. Cl. 430/5; 700/121

(57) ABSTRACT

Disclosed is a method for forming an etching mask, capable of precisely and easily forming an etching mask having a microscopic pattern of a non-straight-line shape. An exposure pattern of a straight-line shape is transferred to a photoresist by using a first reticle and developed, and after a trimming process, a SiO₂ layer is etched by using it as a mask. Thereafter, an exposure pattern of a straight-line shape is transferred to a photoresist by using a second reticle and developed, and then, a protruding amount of an end portion of the photoresist protruding from the SiO₂ layer is measured. Subsequently, the pattern of the photoresist is trimmed to have a preset thickness and length, and by forming the protruding amount to have a preset amount or less, and by using this as a mask, a Si₃N₄ layer is etched, thereby forming an etching mask having an approximately L-shape.

### FIELD OF THE INVENTION

The present disclosure relates to a method for forming an etching mask for use in performing an etching process such as a plasma etching on a substrate such as a semiconductor wafer, and also relates to a control program and a program storage medium.

### BACKGROUND OF THE INVENTION

In a conventional manufacturing process of a semiconductor device, microscopic circuit patterns and the like are formed by performing an etching process such as a plasma etching or the like on a substrate such as a semiconductor wafer or the like. In the etching process, an etching mask is formed by a photolithography process using a photoresist.

In the field of the photolithography process, various types of techniques have been developed to cope with miniaturization of the patterns to be formed. One of such techniques is so-called double patterning. The double patterning is a technique of patterning in two steps including a first mask pattern forming step and a second mask pattern forming step which is performed after the first mask pattern forming step, thus capable of forming an etching mask having a finer pitch than that in case of forming an etching mask by performing the patterning only one time (see, for example, Patent Document 1).

Further, there is also known a method for accomplishing the miniaturization of the patterns by applying an OPC (Optical Proximity Correction) to a reticle used in an exposure of the photoresist. As for the reticle to which the OPC technology is applied, it may be a relatively simple pattern in case of a mask pattern of a simple straight-line shape. However, in case of forming a mask pattern of a non-straight-line shape, such as an L-shaped mask pattern (photoresist pattern) 1 as illustrated in FIG. 4A, a reticle used in an exposure may be a pattern having a complicated shape such as a pattern 2 shown in FIG. 4B.
[Patent Document 1] Japanese Patent Laid-open Publication No. 2007-027742

As mentioned above, in the conventional technique, there occurs a problem that the reticle may have a complicated pattern when forming a fine mask pattern of a non-straight-line shape such as an L-shaped mask pattern or the like.

Further, if the L-shaped mask pattern or the like is formed by employing the double patterning technique, i.e., by using a straight-line-shaped pattern obtained in the first mask pattern forming step and a straight-line-shaped pattern obtained in the second mask pattern forming step, there is a likelihood that the two straight-line-shaped patterns are separated when a gap is formed between the two straight-line-shaped patterns, and if a gate or the like is formed by using such mask patterns, the resultant gate might be in an electrically disconnected state.

For this reason, to prevent the separation of the two straight-line-shaped patterns, it is required to overlap the two line-shaped patterns such that their end portions are protruded. However, if the protruding amount is too big, there arises a likelihood that an electric short circuit with a neighboring pattern may occur. Therefore, a method for removing the protruding portions by etching has been considered, but there has been a problem that a control (stitching control) of the overlapped portions becomes complicated and troublesome in such case.

### BRIEF SUMMARY OF THE INVENTION

In view of the foregoing, the present disclosure provides a method for forming an etching mask, capable of precisely and easily forming an etching mask having a microscopic pattern of a non-straight-line shape, without having to use a reticle having a complicated pattern, and also relates to a control program and a program storage medium.

In accordance with one aspect of the present invention, there is provided a method for forming an etching mask for use in etching a target etching layer on a substrate into a preset pattern, the method including: a first mask pattern forming step; and a second mask pattern forming step performed after the first mask pattern forming step, wherein a first pattern formed in the first mask pattern forming step and a second pattern formed in the second mask pattern forming step have at least one overlapped portion, the first mask pattern forming step includes a first pattern trimming step and a first mask etching step, the second mask pattern forming step includes a second pattern trimming step and a second mask etching step, and said at least one overlapped portion is formed by reducing and correcting a protruding amount of a protruding portion in the second pattern trimming step.

The substrate has a second mask layer formed on the target etching layer and a first mask layer formed on the second mask layer, the first pattern is formed on the first mask layer in the first mask pattern forming step, and the second pattern is formed on the second mask layer in the second mask pattern forming step.

The first pattern and the second pattern are not on the same line at the overlapped portion.

The second pattern trimming step trims the second pattern to a preset length at the same time.

In accordance with another aspect of the present invention, there is provided a control program which is executed on a computer, for controlling an apparatus for forming an etching mask for use in etching a target etching layer on a substrate into a preset pattern, wherein, when executed, the control program controls the apparatus for forming the etching mask to perform the method for forming the etching mask.

In accordance with still another aspect of the present invention, there is provided a program storage medium for storing therein a computer-executable control program for controlling an apparatus for forming an etching mask for use in etching a target etching layer on a substrate into a preset pattern, wherein, when executed, the control program controls the apparatus for forming the etching mask to perform the method for forming the etching mask.

In accordance with the present disclosure, it is possible to provide a method for forming an etching mask, capable of precisely and easily forming an etching mask having a microscopic pattern of a non-straight-line shape, without having to use a reticle having a complicated pattern, and also to provide a control program and a program storage medium.

### BRIEF DESCRIPTION OF THE DRAWINGS

The disclosure may best be understood by reference to the following description taken in conjunction with the following figures:

FIG. 1 is a diagram showing a schematic configuration in accordance with an embodiment of the present invention;

FIGS. 2A to 2I are diagrams for describing a process in accordance with the embodiment of the present invention;

FIG. 3 is a diagram showing a schematic configuration of an apparatus for use in the embodiment of the present invention; and

FIGS. 4A and 4B are diagrams for describing the prior art.

### DETAILED DESCRIPTION OF THE INVENTION

Hereinafter, an embodiment of the present invention will be described in detail with reference to the accompanying drawings.

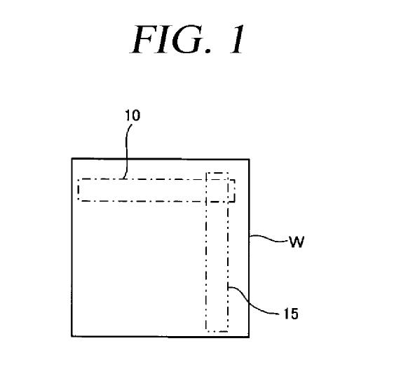

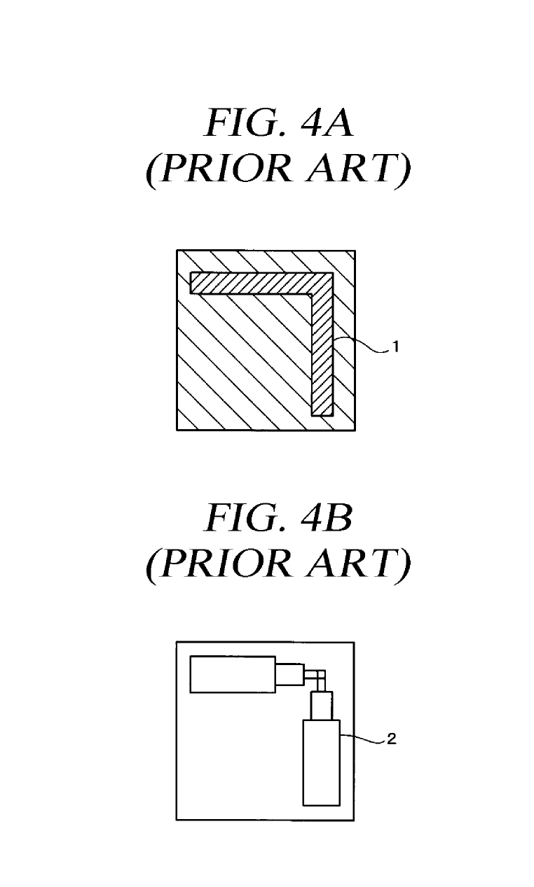

FIG. 1 is an enlarged view schematically illustrating a part of a semiconductor wafer W in accordance with the embodiment of the present invention. In the present embodiment, as illustrated by dashed lines in the figure, two reticles respectively having an exposure pattern 10 of a straight-line shape and an exposure pattern 15 of a straight-line shape are used, and a substantially L-shaped etching mask is formed on the semiconductor wafer W by performing an exposure process such that end portions of the straight-lines are overlapped. As such, by using the two reticles each having the exposure pattern of the straight-line shape instead of an exposure pattern of a non-straight-line shape having a corner portion, an OPC model can be simplified, so that it becomes unnecessary to use a reticle of a complicated pattern as shown in FIGS. 4A and 4B.

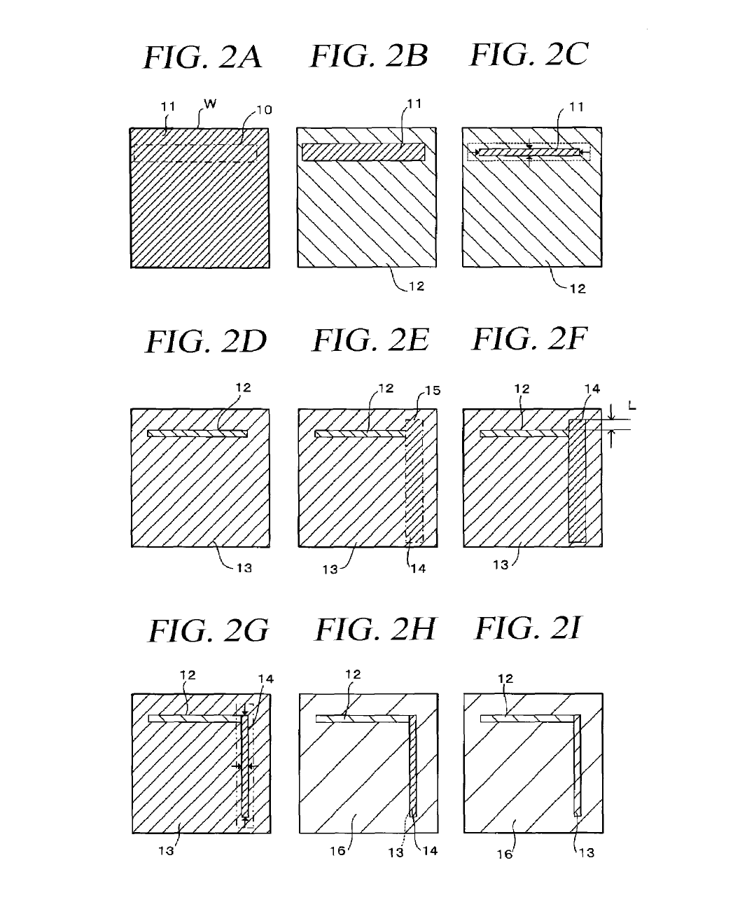

FIGS. 2A to 2I schematically illustrate a process of forming the etching mask in accordance with the embodiment of the present invention. In the present embodiment, as shown in the figures, an exposure is first performed on a photoresist 11 formed on the semiconductor wafer W by using a first reticle to thereby transfer the exposure pattern 10 of the straight-line shape thereto (FIG. 2A).

Subsequently, a developing process of the photoresist 11 is carried out, so that the photoresist 11 in the same shape as the exposure pattern remains, and a SiO₂ layer 12 formed on a surface of the semiconductor wafer W is exposed at portions other than where the photoresist 11 exists (FIG. 2B).

Thereafter, a first pattern trimming step is performed, so that the pattern of the photoresist 11 is shrunk to have a preset thickness and length (FIG. 2C).

Then, a first mask etching step is performed by using the pattern of the shrunk photoresist 11 as a mask to etch the SiO₂ layer 12 serving as a first mask layer. Resultantly, the SiO₂ layer 12 remains in the shape of the pattern of the shrunk photoresist 11, and the photoresist 11 is removed by ashing (FIG. 2D). In this state, an underlying Si₃N₄ layer (second mask layer) 13 is exposed at portions other than where the SiO₂ layer 12 exists.

The above-described process constitutes a first mask pattern forming step through which a first pattern of a straight-line shape made of the SiO₂ layer 12 serving as the first mask layer is formed on the semiconductor wafer W. Then, a second mask pattern forming step as follows is performed subsequently.

In the second mask pattern forming step, a photoresist 14 is again coated onto the semiconductor wafer W, and an exposure is performed on the photoresist 14 by using a second reticle, so that an exposure pattern 15 of a straight-line shape is transferred thereto (FIG. 2E). Further, FIG. 2E shows a state after developing the photoresist 14. In this process, to allow an end portion of the exposure pattern 15 to be securely overlapped with an end portion of the straight-line-shaped first pattern made of the SiO₂ layer 12, the transfer of the exposure pattern 15 is carried out by adjusting a position thereof such that a portion of the exposure pattern 15 is protruded.

Subsequently, in the state where the photoresist 14 in the shape of the exposure pattern remains after the developing process, the protruding amount (i.e., a length L shown in FIG. 2F) of the end portion of the photoresist 14, which is protruded from the straight-line-shaped first pattern formed in the first mask pattern forming step and made of the SiO₂ layer 12, is measured (FIG. 2F).

Thereafter, a second pattern trimming step is carried out, so that the pattern of the photoresist 14 is trimmed to have a preset thickness and length (FIG. 2G). At this time, the shrunk amount is controlled such that the protruding amount (the length L shown in FIG. 2F) does not exceed a preset amount.

Subsequently, a second mask etching step is performed by using the pattern of the shrunk photoresist 14 as a mask to etch the Si₃N₄ layer 13 serving as the second mask layer (FIG. 2H). Resultantly, the Si₃N₄ layer 13 remains in the shape of the pattern of the shrunk photoresist 14 while an underlying polysilicon layer 16 is exposed, and the photoresist 14 is removed by ashing (FIG. 2I).

Through the above-described process, a substantially L-shaped etching mask can be formed, and by using the substantially L-shaped etching mask, etching of the polysilicon layer 16 is performed later, thus patterning the polysilicon layer 16 in a substantially L-shape.

Further, though the embodiment has been described for the case of forming the substantially L-shaped etching mask, the present disclosure can also be applied to a formation of an etching mask of any of various non-straight-line shapes, such as an etching mask of a substantially one-side opened rectangular shape, an etching mask having a bent portion at an angle other than a right angle, or the like.

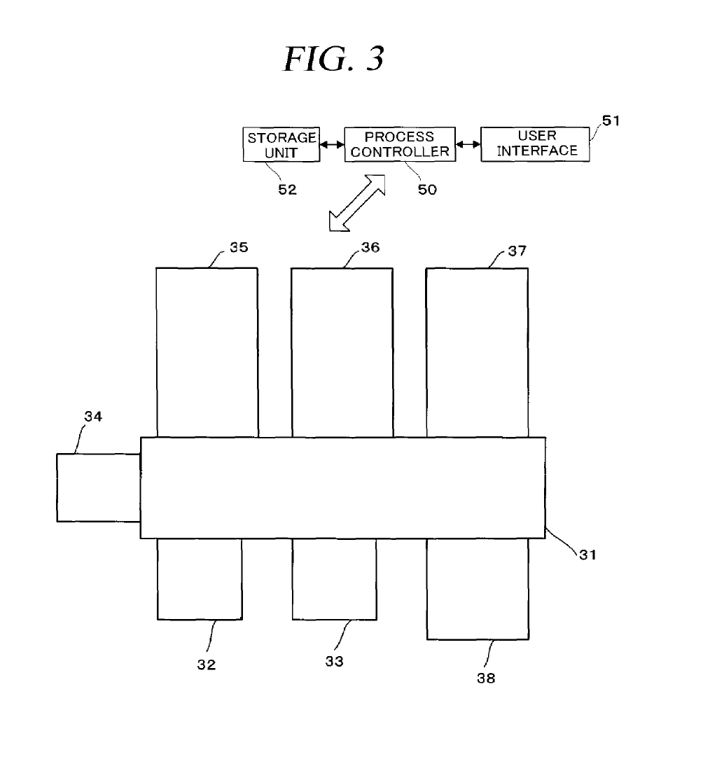

FIG. 3 is a top view schematically showing an example configuration of an apparatus for performing the above-described etching mask forming method. The apparatus includes a rectangular shaped transfer unit 31 provided with a transfer mechanism for transferring a semiconductor wafer W to an inside thereof. Provided at one side (lower side in the figure) along a lengthwise direction of the transfer unit 31 are a plurality of mounting units 32 and 33 for mounting thereon cassettes or FOUPs accommodating the semiconductor wafer W, and a measuring device 38 for measuring a critical dimension (CD) of a desired portion of a pattern formed on the semiconductor wafer W. Further, a multiplicity of plasma etching processing units 35 to 37 for performing an etching process on the semiconductor wafer W is installed at the other side (upper side in the figure) along the lengthwise direction of the transfer unit 31.

Furthermore, a position alignment device 34 for performing a position alignment of the semiconductor wafer W is provided at one end portion of the transfer unit 31. The semiconductor wafer W taken out of the cassette or FOUP mounted on the mounting unit 32 or 33 by the transfer mechanism is first conveyed into the position alignment device 34, and after the position alignment is carried out therein, the semiconductor wafer W is sent into each of the plasma etching processing units 35 to 37 and the measuring device 38 so that the etching process and the measurement of the critical dimension (CD) of the desired portion are performed. After the completion of the process, the semiconductor wafer W is re-accommodated in the cassette or FOUP mounted on the mounting unit 32 or 33.

Each component of the apparatus is controlled by a process controller 50. The process controller 50 is connected with a user interface 51. The user interface 51 includes a keyboard for performing an input operation of a command or the like, a display for visualizing and displaying an operational status of the apparatus, and the like.

Further, the process controller 50 is connected to a storage unit 52 storing therein recipes, i.e., control programs to be used in executing various processes performed by the apparatus under the control of the process controller 50, or control programs to be used in operating each component of the apparatus according to processing conditions. The recipes may be stored in a program storage medium such as a hard disk or a semiconductor memory, or they can also be stored in a portable program storage medium such as a CD-ROM, a DVD or the like so as to be set in a specific position of the storage unit 52. Alternatively, it is possible to properly transmit the recipes from another apparatus through, for example, a dedicated line.

Further, a necessary recipe is retrieved from the storage unit 52 in response to an instruction from the user interface 51 or the like and is executed by the process controller 50, so that a desired process is performed in the apparatus under the control of the process controller 50.

By using the apparatus having the above-described configuration, it is possible to form the etching mask by measuring the above-mentioned protruding amount (the length L shown in FIG. 2F) and performing the etching process of the SiO₂ layer 12 and the etching process of the Si₃N₄ layer 16.

The above description of the present invention is provided for the purpose of illustration, and it would be understood by those skilled in the art that various changes and modifications may be made without changing technical conception and essential features of the present invention. Thus, it is clear that the above-described embodiments are illustrative in all aspects and do not limit the present invention.

The scope of the present invention is defined by the following claims rather than by the detailed description of the embodiment. It shall be understood that all modifications and embodiments conceived from the meaning and scope of the claims and their equivalents are included in the scope of the present invention.

What is claimed is:

1. A method for forming an etching mask for use in etching a target etching layer on a substrate into a preset pattern, the method comprising:
a first mask pattern forming step; and
a second mask pattern forming step performed after the first mask pattern forming step,
wherein a first pattern formed in the first mask pattern forming step and a second pattern formed in the second mask pattern forming step have at least one overlapped portion,
the first mask pattern forming step includes a first pattern trimming step and a first mask etching step,
the second mask pattern forming step includes a second pattern trimming step and a second mask etching step, and
said at least one overlapped portion is formed by reducing and correcting a protruding amount of a protruding portion in the second pattern trimming step.

2. The method of claim 1, wherein the substrate has a second mask layer formed on the target etching layer and a first mask layer formed on the second mask layer,
the first pattern is formed on the first mask layer in the first mask pattern forming step, and
the second pattern is formed on the second mask layer in the second mask pattern forming step.

3. The method of claim 1, wherein the first pattern and the second pattern are not on the same line at the overlapped portion.

4. The method of claim 1, wherein the second pattern trimming step trims the second pattern to a preset length at the same time.

5. A control program which is executed on a computer, for controlling an apparatus for forming an etching mask for use in etching a target etching layer on a substrate into a preset pattern, wherein,
when executed, the control program controls the apparatus for forming the etching mask to perform a method for forming an etching mask as claimed in claim 1.

6. A program storage medium for storing therein a computer-executable control program for controlling an apparatus for forming an etching mask for use in etching a target etching layer on a substrate into a preset pattern, wherein,
when executed, the control program controls the apparatus for forming the etching mask to perform a method for forming an etching mask as claimed in claim 1.
